(19) United States
(12) Patent Application Publication
(10) Pub. No.: US 2014/0361726 A1
(43) Pub. Date: Dec. 11, 2014

(54) System and Method for Assuring Operational Readiness of a Mission Critical Battery Having a Long Storage Period

(71) Applicant: Panacis Inc., Ottawa (CA)

(72) Inventor: Steve Carkner, Ottawa (CA)

(73) Assignee: PANACIS, INC., Ottawa, OT (CA)

(21) Appl. No.: 14/365,097

(22) PCT Filed: Dec. 19, 2012
(86) PCT No.: PCT/CA2012/050916

§ 371 Date: Jun. 12, 2014

Related U.S. Application Data
(60) Provisional application No. 61/584,717, filed on Jan. 9, 2012.

(51) Int. Cl. H02J 7/00; G01R 31/36

(52) U.S. Cl. CPC H02J 7/0054; H02J 7/007; G01R 31/3606
USPC 320/103

(57) ABSTRACT

A system and method for ensuring the readiness of a mission critical battery in a device, the system includes a rechargeable battery as the mission critical battery disposed within the device slaved to a primary charging battery through a charge controller both of which are disposed outside of the device. The charge controller is programmed to ensure that the primary charging battery delivers a charge to the mission critical battery to maintain the mission critical battery at a charge level for maximized long term storage. The storage charge level may be 50% of the full charge level of the mission critical battery. The charge controller will receive a mission signal when the device is to be mission ready. The charge controller will then transfer the appropriate amount of stored energy from the primary charging battery to the mission critical battery to achieve full charge.

### TECHNICAL FIELD

This invention relates to the field of batteries designed for very long shelf-life or dormancy prior to discharge. The period of dormancy may be greater than 20 years. Specifically the invention is a system and method for assuring the operational readiness of a mission critical battery after a lengthy storage or dormancy period.

### BACKGROUND ART

### Disclosure of Invention

### Technical Problem

Technical P Primary batteries with shelf life of 10 years or more exist, but cannot be recharged. These batteries will provide energy to a system only once. It is therefore impossible to properly test the remaining capacity of such a battery without discharging it and therefore rendering it empty. Although methods of reading the voltage or placing small test discharges on the cells have been suggested, in high reliability environments, especially over longer time periods such as 20 years, it is unlikely that such systems will provide an adequate test of the battery's ability to support a load.

Primary batteries, in general, lack the ability to deliver high amount of energy rapidly, as may be required by the application. This is especially true in very long shelf-life batteries such as Silver-Oxide cells.

Rechargeable batteries with a shelf life of greater than 10 years do not exist. In this case the shelf life would be defined as the time the battery can be placed in storage without any recharging, and still maintain a useful amount of energy. The advantage of rechargeable batteries is that they can be tested by completing a discharge/recharge cycle. In this way the exact capacity and function of the battery can be periodically verified. Rechargeable batteries are also, generally, capable of high discharge rates and can be easily optimized to power high transient loads.

The normal approach to ensuring adequate energy levels after long periods of storage is to use grossly oversized batteries. This approach is incompatible for systems where size and weight are important.

There is a need for a system and method of assuring the operational readiness of a mission critical battery after a lengthy storage period of at least 20 years. The system must permit testing of the mission critical battery to verify capacity and needs to be as light as possible while also powering high transient loads.

### PROBLEM

### Solution to Problem

### Technical Solution

The invention uses a hybrid approach to and comprises a primary charging battery that is slaved to a rechargeable secondary battery. A primary charging battery has a charge control system and is used to maintain the rechargeable secondary battery at an optimum state of charge over a very long period of dormancy or storage. When operation of the secondary battery is required, the primary charging battery is used to quickly top-up the rechargeable secondary battery to a full state of charge.

To reduce overall weight the primary battery is placed externally to the device being powered by the secondary battery.

For example, a missile system may rely upon an internal rechargeable secondary battery to power missile systems during flight. This is a mission critical battery that must be fully charged at the time the missile is launched. The rechargeable secondary battery could be connected to an external primary charging battery having charging control system. The primary charging battery is external to the missile and does not launch with the missile so that missile weight is not compromised. During missile dormancy or storage the external primary charging battery will keep the secondary rechargeable battery at an optimum state of charge to prolong the life of the secondary battery over a long dormancy period. This optimum state of charge for a long dormancy period may be 50% or less than the full-charge operational level for the battery. The actual optimum charge level will vary depending on the rechargeable battery chemistry and environmental factors.

When the missile is activated and prior to launch, the primary charging battery will dump power at high rate into the rechargeable secondary battery to bring it up to a full state of charge for the mission.

Testing of the secondary rechargeable battery can be accomplished by forcing a charge/discharge/charge cycle using the charge controlling on the primary charging battery. The primary charging battery can be periodically tested and replaced, if required, without disturbing the rechargeable battery.

It is expected that the primary battery would have a capacity that is at least twice that of the secondary rechargeable battery. This ensures that the energy required to keep the rechargeable battery at an optimal state of 50% charge for lengthy dormancy is available while also ensuring that adequate energy will be available to bring the rechargeable battery up to full capacity when and if required.

### ADVANTAGEOUS EFFECTS OF INVENTION

### Advantageous Effects

### BRIEF DESCRIPTION OF DRAWINGS

### Description of Drawings

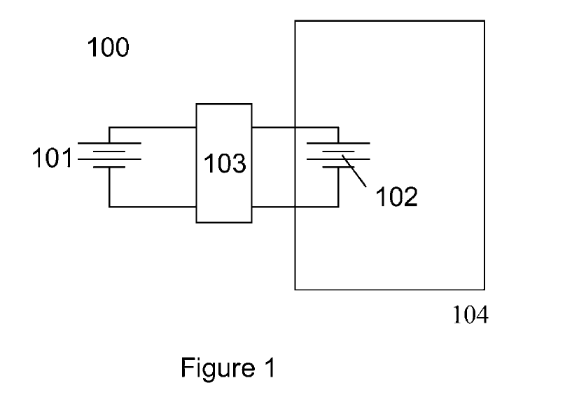

FIG. 1 shows a schematic representation of one embodiment of the invention.

### BEST MODE FOR CARRYING OUT THE INVENTION

### Best Mode

Referring to FIG. 1, system of the invention (100) comprises a primary battery (101) that is used to maintain a long-term storage charge on the secondary rechargeable battery (102). The primary battery may be one of a single-use lithium battery, an Alkaline battery, an Aluminium battery, a Bunsen cell, a Chromic acid cell, a Clark cell, a Daniell cell, a Dry cell, a Grove cell, a Leclanche cell, a Mercury battery, a Nickel oxyhydroxide battery, a Silicon-air battery, a Silver-oxide battery, a Weston cell, a Zamboni pile, a Zinc-air battery, a Zinc-carbon battery, a Zinc-chloride battery or any other primary battery technology.

The rechargeable secondary and mission critical battery (102) can be one of a lithium ion battery, a lithium polymer battery, a nickel metal hydride battery, or any other suitable secondary battery technology capable of being recharged.

In one preferred embodiment of the system of the invention the secondary rechargeable battery (102) is stored inside the housing (104) of the device to be powered, for example, a missile. The primary charging battery (101) and the charge control system (103) would reside outside of housing (104) and be detached prior to system use (such as missile launch).

During an expected lengthy period of dormancy or storage, the control system (103) will deliver energy from the primary charging battery (101) to the rechargeable secondary battery (102). The rate of charge will ensure that the rechargeable secondary battery remains at an optimal state of charge during storage. This optimal storage charge may be 50% of full battery charge. The control system (103) includes means, such as a semiconductor switch, to control the energy transfer and is capable of rapid energy transfer when the control system (103) receives a signal to bring the rechargeable battery to full charge. The control signal may be a button press, switch activation, wired signal or wireless signal.

While the diagrams, explanations and labelling of the systems presented herein refer specifically to electrochemical cell types, polarities and connections, it can be appreciated that one skilled in the art may implement a system with similar intent. Monitoring current on the negative side of the battery module, implementing a different chemistry or varying the size, number or interconnection of the modules shall all be considered part of this application.

### MODE FOR THE INVENTION

### Mode for Invention

### INDUSTRIAL APPLICABILITY

### Sequence Listing Free Text

Sequence List Text

1. A system for assuring operational readiness of a mission critical battery in a stored device, said mission critical battery having a long storage period, said system comprising:
a. a primary charging battery for storing an electrical charge connected to;
b. a charging control circuit disposed between said primary charging battery and;
c. connected to the mission critical battery, wherein the mission critical battery is a rechargeable battery having a first predetermined storage charge that is less than a second mission full charge; and,
d. wherein said charging control circuit receives a mission signal to transfer said electrical charge from the primary charging battery to the mission critical battery thereby bringing the mission critical battery to the mission full charge.

2. The system of claim 1 wherein said predetermined storage charge is dependent upon said long storage period.

3. The system of claim 2 wherein the predetermined storage charge is generally less than 50% of mission full charge.

4. The system of claim 2 wherein the predetermined storage charge is 50% of mission full charge.

5. The system of claim 1 wherein the primary charging battery is disposed outside of said stored device.

6. The system of claim 1 wherein the secondary rechargeable battery has a predetermined energy storage capacity and wherein said primary charging battery electrical charge is at least twice said predetermined energy storage capacity.

7. A method for assuring operational readiness of a mission critical battery in a stored device, said mission critical battery having a long storage period, said method comprising the following steps:
a. Using a rechargeable battery for the mission critical battery;
b. Connecting said rechargeable battery to a charging battery having a predetermined energy storage capacity;
c. Disposing a charge control circuit between the rechargeable battery and said charging battery;
d. Determining a full charge for the mission critical battery;
e. Determining a dormancy charge for the mission critical battery that will maximize said long storage period;
f. Programming said charge control circuit to maintain the mission critical battery at said dormancy charge for the long storage period;
g. Transferring a first suitable amount of said predetermined storage capacity to the mission critical battery to achieve the dormancy charge;
h. Establishing a testing protocol to maintain the mission critical battery in a reliable state.

8. The method of claim 7 wherein the charge control circuit receives a mission signal, the method further comprising the steps of:
a. Processing said mission signal; and,
b. Transferring a second suitable amount of the predetermined storage capacity to the mission critical battery to achieve said full charge.

9. The method of claim 7 wherein said testing protocol comprises the steps of:
a. Setting the charge controller to a mission critical battery test mode;
b. The charge controller forcing a charge/discharge/charge cycle on the mission critical battery;
c. Detecting a fault on the mission critical battery; and. d. Replacing the mission critical battery as necessary.

10. The method of claim 7 wherein said testing protocol comprises the steps of :
a. Setting the charge controller to a primary charging battery test;
b. The charge controller forcing a discharge/charge/discharge cycle on the primary charging battery;
c. Detecting a fault in the primary charging battery; and,
d. Replacing the primary charging battery as required.
